(19) United States
(12) Patent Application Publication
(10) Pub. No.: US 2015/0192854 A1
(43) Pub. Date: Jul. 9, 2015

(54) COMPOSITION FOR MANUFACTURING INTEGRATED CIRCUIT DEVICES, OPTICAL DEVICES, MICROMACHINES AND MECHANICAL PRECISION DEVICES

(71) Applicant: BASF SE, Ludwigshafen (DE)

(72) Inventors: Andreas Klipp, Lambsheim (DE); Andrei Honciuc, Ludwigshafen (DE); Sabrina Montero Pancera, Taipei (TW); Zoltan Baan, Maxdorf (DE)

(73) Assignee: BASF SE, Ludwigshafen (DE)

(21) Appl. No.: 14/413,252

(22) PCT Filed: Jul. 12, 2013
(86) PCT No.: PCT/IB2013/055728

§ 371 Date: Jan. 7, 2015

Related U.S. Application Data
(60) Provisional application No. 61/671,806, filed on Jul. 16, 2012.

(51) Int. Cl. G03F 7/32; G03F 7/20

(52) U.S. Cl. CPC G03F 7/32; G03F 7/2002; G03F 7/2041

(57) ABSTRACT

A composition comprising a quaternary ammonium compound for developing photoresists applied to semiconductor substrates is provided. A method for manufacturing integrated circuit devices, optical devices, micromachines and mechanical precision devices is also provided. The pattern collapse can be avoided by prevent swelling of the photoresist by using the improved composition.

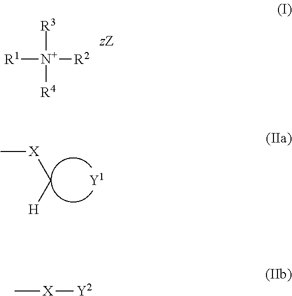

The present invention is directed to a composition useful in processes for manufacturing integrated circuits devices, optical devices, micromachines and mechanical precision devices, in particular to photoresist development compositions.

### BACKGROUND OF THE INVENTION

In the process of manufacturing ICs with LSI, VLSI and ULSI, patterned material layers like patterned photoresist layers, patterned barrier material layers containing or consisting of titanium nitride, tantalum or tantalum nitride, patterned multi-stack material layers containing or consisting of stacks e.g. of alternating polysilicon and silicon dioxide layers, and patterned dielectric material layers containing or consisting of silicon dioxide or low-k or ultra-low-k dielectric materials are produced by photolithographic techniques. Nowadays, such patterned material layers comprise structures of dimensions even below 22 nm with high aspect ratios.

In the photolithography process, a radiation-sensitive photoresist is applied to a substrate such as a wafer and then an image exposure is transmitted to the photoresist, usually through a mask. Depending on the type of photoresist used, exposure will either increase or decrease the solubility of the exposed areas with a suitable solvent called a developer. A positive photoresist material will become more soluble in exposed regions whereas a negative photoresist will become less soluble in exposed regions. After exposure, regions of the substrate are dissolved by the developer and no longer covered by the patterned photoresist film and the circuit pattern may now be formed either by etching or by depositing a material in the open patterned areas.

An optional post-exposure bake (PEB) is often performed to allow the exposed photoresist polymers to cleave. The substrate including the cleaved polymer photoresist is then transferred to a developing chamber to remove the exposed photoresist, which is soluble in aqueous developing compositions. Typically, such developing compositions comprise tetraalkylammonium hydroxides, such as but not limited to tetramethylammonium hydroxide (TMAH) are applied to the resist surface in the form of a puddle to develop the exposed photoresist. A deionized water rinse is then applied to the substrate to stop the development process and to remove the dissolved polymers of the photoresists. The substrate is then sent to a spin drying process. Thereafter, the substrate can be transferred to the next process step, which may include a hard bake process to remove any moisture from the photoresist surface.

Due to the shrinkage of the dimensions, the removal of particles in order to achieve a defect reduction becomes also a critical factor. This does not only apply to photoresist patterns but also to other patterned material layers, which are generated during the manufacture of optical devices, micromachines and mechanical precision devices. The swelling of the photoresist in the photoresist developing step is an important factor, which may increase the risk of pattern collapse and should therefore be avoided.

U.S. Pat. No. 7,214,474 B2 discloses a wash composition comprising a first polymeric surfactant, wherein the first polymeric surfactant is a polymer selected from the group consisting of poly(dodecylacrylate-co-sodium acrylate), poly(styrene-co-a-methy !styrene-co-acrylic acid), poly(acrylic acid-co-methyl methacrylate), poly(acrylic acid) with hydrophobic modifications, poly(vinylnaphtalene-alt-maleic acid)-g-polystyrene, and a polysoap having the structure:

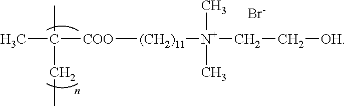

U.S. Pat. No. 6,451,510 B2 discloses a method for developing a photoresist pattern on an electronic component substrate for avoiding collapse of the developed pattern. In one step a rinse water solution is supplied on the wet developed substrate, the rinse water solution comprising deionized water and an anionic surfactant in an amount sufficient to avoid collapse of the pattern. The developer solution may comprise tetraalkylammonium hydroxides, in particular tetramethyl ammonium hydroxide (TMAH) and trimethyl 2-hydroxyethyl ammonium hydroxide, i.e., choline. Other ammonium hydroxides include tetraethylammonium hydroxide, tetrapropylammonium hydroxide, tetrabutylammonium hydroxide, methyltriethyl ammonium hydroxide, trimethylethylammonium hydroxide, dimethyldiethylammonium hydroxide, triethyl(2-hydroxyethyl)ammonium hydroxide, dimethyldi(2-hydroxyethyl)ammonium hydroxide, diethyldi(2-hydroxyethyl) ammonium hydroxide, methyltri(2-hydroxyethyl)ammonium hydroxide, ethyltri(2-hydroxy [symbol] ethyl)ammonium hydroxide, and tetra(2-hydroxyethyl)ammonium hydroxide.

WO 2012/027667 A2 discloses a method of modifying a surface of a high aspect ratio feature to avoid pattern collapse. Surfactants like tetrabutylammonium trifluoromethanesulfonate and dodecyltrimethylammonium are used.

US 2004/0106532 A1 discloses the use of a composition for stripping and dissolving a photoresist pattern having a film thickness of 10-150 micrometers, comprising C₁ to C₆ alkyl quaternary ammonium compounds. Tetrabutylammonium hydroxide and methyltributylammonium hydroxide are used in the composition along with water-soluble organic solvents like dimethyl sulfoxide and water.

EP 2088468 A1 discloses a method of preparing lithographic printing plate and lithographic printing plate precursor. By means of a binder polymer containing a carboxylic acid group, a sulfonic acid group and a phosphoric acid group in the form of an ammonium salt bulky groups like adamantyl or dicyclohexyl may be introduced into the photoresist. However, the developer used therein does not contain any ammonium compounds comprising such bulky groups.

### Objects of the Invention

In summary, pattern collapse may generally be caused by:
A. Swelling of the photoresist in the developing phase,
B. Capillary action of the rinsing/cleaning composition during the liquid spin-off at the end of the rinse,
C. Poor adhesion of the patterned structures to the underlayer,
D. Material incompatibility leading to swelling and weakening of the structures.

The present invention mainly addresses the problems under Lit. A, i.e. to prevent swelling of the photoresist by using an improved developer composition.

It is an object of the present invention to provide a composition for use in developing a photoresist pattern on an electronic component substrate such as a semiconductor wafer to avoid pattern collapse of the developed photoresist.

It is another object of the present invention to provide a method for developing a photoresist pattern on an electronic component substrate such as a semiconductor wafer to avoid pattern collapse of the developed photoresist.

### SUMMARY OF THE INVENTION

A first embodiment of the present invention is an aqueous composition for developing photoresists applied to semiconductor substrates, said aqueous composition comprising a quaternary ammonium compound of formula I

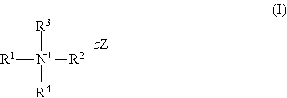

wherein
(a) R¹ is selected from a C₄ to C₃₀ organic radical of formula —X—CR¹⁰R¹¹R¹², wherein R¹⁰, R¹¹ and R¹² are independently selected from a C₁ to C₂₀ alkyl and two or three of R¹⁰, R¹¹ and R¹² may together form a ring system, and
   R², R³ and R⁴ are independently selected from R¹ or a C₁ to C₁₀ alkyl, C₁ to C₁₀ hydroxyalkyl, C₁ to C₃₀ aminoalkyl or C₁ to C₂₀ alkoxyalkyl, and X is a chemical bond or a C₁ to C₄ divalent organic radical, or
(b) R¹ and R² are independently selected from an organic radical of formula IIa or IIb

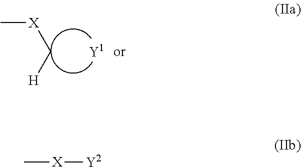

wherein Y¹ is C₄ to C₂₀ alkanediyl, Y² is a one-, two- or tricyclic C₅ to C₂₀ carbocyclic or heterocyclic aromatic system, and R³ and R⁴ are selected from R¹ or a C₁ to C₁₀ alkyl, C₁ to C₁₀ hydroxyalkyl, C₁ to C₃₀ aminoalkyl, or C₁ to C₂₀ alkoxyalkyl, and X is a chemical bond or a C₁ to C₄ divalent organic radical, and X is a chemical bond or a C₁ to C₄ divalent organic radical, or
(c) at least two of R¹, R², R³, and R⁴ together form a saturated mono, bi or tricyclic C₅ to C₃₀ organic ring system and the remaining R³ and R⁴, if any, together form a monocyclic C₅ to C₃₀ organic ring system or are selected from a C₁ to C₁₀ alkyl, C₁ to C₁₀ hydroxyalkyl, C₁ to C₃₀ aminoalkyl, or C₁ to C₂₀ alkoxyalkyl, and X is a chemical bond or a C₁ to C₄ divalent organic radical, or
(d) a combination thereof, and
   wherein Z is a counter-ion and z is an integer, which is chosen so that the overall bulky quaternary ammonium compound is electrically uncharged.

Another embodiment of the present invention is the use of a composition according to anyone of the preceding claim for developing photoresist layers applied to semiconductor substrates to obtain a patterned photoresist layer having line-space dimensions of 50 nm or less and an aspect ratio of 2 or more.

Yet another embodiment of the present invention is a method for manufacturing integrated circuit devices, optical devices, micromachines and mechanical precision devices comprising the steps of
(i) providing a substrate
(ii) providing the substrate with a photoresist layer;
(iii) exposing the photoresist layer to actinic radiation through a mask with or without an immersion liquid;
(iii) contacting the substrate at least once with a composition according to anyone of claims the preceding claims to obtain a patterned photoresist layer;
   and
(iv) removing the composition from the contact with the substrate.

### Advantages of the Invention

In view of the prior art, it was surprising and could not be expected by the skilled artisan that the objects of the invention could be solved by the use or method according to the invention.

Without to be bound to any theory, it seems that the use of bulky alkyl ammonium compounds in the developer compositions could prevent swelling of the photoresist layer due to reduced diffusion.

Furthermore the use of a surface active bulky ammonium compound it may be possible to lower the surface tension of the developer composition and thereby further reducing pattern collapse.

The photoresist surface after developing is more hydrophobic due to the more hydrophobic alkyl substituents compared to the developers according to the prior art. Without to be bound to any theory it is believed that both, reduced swelling of the photoresist as well as the more hydrophobic surface of the photoresist is beneficial for pattern collapse reduction.

### DETAILED DESCRIPTION OF THE INVENTION

The composition according to the invention is used for stripping and dissolving a photoresist pattern that is formed on a substrate. An essential component in the developer composition is one or more quaternary ammonium represented by the following general formula (Ia):

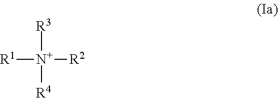

The quaternary ammonium compounds according to the invention are referred to as bulky ammonium compounds in the following.

A counter-ion Z has to be present in an amount so that the overall bulky ammonium compound is electrically uncharged.

In a first embodiment of the present invention R¹ of formula I is selected from a C₄ to C₃₀ organic radical of formula —X—CR¹⁰R¹¹R¹², wherein R¹⁰, R¹¹ and R¹² are independently selected from a C₁ to C₂₀ alkyl and two or three of R¹⁰, R¹¹ and R¹² may together form a ring system, and R², R³ and R⁴ are selected from R¹ or a C₁ to C₁₀ alkyl, C₁ to C₁₀ hydroxyalkyl C₁ to C₃₀ aminoalkyl or C₁ to C₂₀ alkoxyalkyl, and X is a chemical bond or a C₁ to C₄ divalent organic radical.

In this embodiment R¹ comprises at least one tertiary carbon atom which makes the group more bulky.

Since bulky groups as disclosed in EP 2088468 A1 are often part of photoresist polymer it is preferred to use the same or chemically similar bulky groups in the developer composition.

Preferably R¹⁰, R¹¹ and R¹² of R¹ are independently selected from C₁ to C₈ alkyl.

Preferably at least two of R¹⁰, R¹¹ and, if applicable, R¹² together form a mono, bi or tri cyclic ring system. In a particularly preferred embodiment R¹ is selected from bicyclo[2.2.1]heptane (norbornyl), Tricyclo[3.3.1.1^{3,7}]decane (adamantyl).

Preferably R², R³ and R⁴ are independently selected from lower linear or branched alkyl, particularly linear C₁ to C₄ alkyl. More preferably R², R³ and R⁴ are independently selected from methyl, ethyl or propyl, most preferably from methyl.

In a particular embodiment of the present invention R¹ is adamantyl and R², R³ and R⁴ are methyl, ethyl, propyl or butyl or any other C₂ to C₄ alkyl:

In a second embodiment of the present invention R¹ and R² of formula I are independently selected from an organic radical of formula IIa or IIb

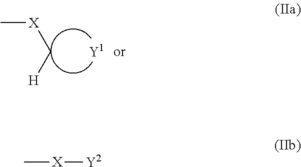

wherein Y¹ is C₄ to C₂₀ alkanediyl, Y² is a one-, two- or tricyclic C₅ to C₂₀ carbocyclic or heterocyclic aromatic system, and R³ and R⁴ are selected from R¹ or a C₁ to C₁₀ alkyl, C₁ to C₁₀ hydroxyalkyl, C₁ to C₃₀ aminoalkyl, or C₁ to C₂₀ alkoxyalkyl, and X is a chemical bond or a C₁ to C₄ divalent organic radical, and X is a chemical bond or a C₁ to C₄ divalent organic radical.

In this embodiment at least R¹ and R² comprise either a cyclic saturated organic group or an aromatic organic group, both of which make the group more bulky.

Y¹ preferably is a carbocyclic saturated organic group, more preferably C₄ to C₂₀ alkanediyl, even more preferably C₅ to C₁₀ alkanediyl, most preferably pentanediyl.

Y² is preferably selected from carbocyclic aromatic compounds, such as but not limited to phenyl, napthyl.

In a particularly preferred embodiment of the present invention R¹ and R² are cyclohexyl and R³ and R⁴ are methyl:

In a third embodiment of the present invention at least two of R¹, R², R³, and R⁴ of formula I together form a saturated mono, bi or tricyclic C₅ to C₃₀ organic ring system and the remaining R³ and R⁴, if any, together form a monocyclic C₅ to C₃₀ organic ring system or are selected from a C₁ to C₁₀ alkyl, C₁ to C₁₀ hydroxyalkyl, C₁ to C₃₀ aminoalkyl, or C₁ to C₂₀ alkoxyalkyl, and X is a chemical bond or a C₁ to C₄ divalent organic radical.

Preferably such saturated mono, bi or tricyclic C₅ to C₃₀ organic ring system is (except the N-atom) a carbocyclic C₅ to C₂₀ organic ring system. Even more preferably such saturated mono, bi or tricyclic C₅ to C₃₀ organic ring system is monocyclic. Most preferably such saturated mono, bi or tricyclic C₅ to C₃₀ organic ring system is selected from piperidine, piperazine, oxazolidine, and morpholine.

Preferably R¹ and R² together form a saturated mono, bi or tricyclic C₅ to C₃₀ organic ring system and R³ and R⁴ may be any group as mentioned with respect to the first and second embodiment described above.

It has to be emphasized that the compounds according to the first, second and third embodiment may also be used in combination. Also the presence of more than one compound of a particular embodiment described above is possible.

Preferably R¹, R² are independently selected from cyclohexyl, cyclooctyl or cyclodecyl, which may be unsubstituted or substituted by C₁ to C₄ alkyl, and R³, R⁴ are independently selected from C₁ to C₄ alkyl.

In a particular embodiment the C₁ to C₃₀ aminoalkyl is selected from

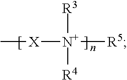

wherein:
X is a divalent group, for each repeating unit 1 to n independently selected from
   (a) linear or branched C₁ to C₂₀ alkanediyl, which may optionally be substituted and which may optionally be interrupted by up to 5 heteroatoms selected from O and N,
   (b) C₅ to C₂₀ cycloalkanediyl, which may optionally be substituted and which may optionally be interrupted by up to 5 heteroatoms selected from O and N,
   (c) C₆ to C₂₀ organic group of formula —X¹-A-X²—, wherein X¹ and X² are independently selected from a C₁ to C₇ linear or branched alkanediyl and A is selected from a C₅ to C₁₂ aromatic moiety or a C₅ to C₃₀ cycloalkanediyl, which H atoms may optionally be substituted and which C atoms may optionally be interrupted by up to 5 heteroatoms selected from O and N,
   (d) polyoxyalkylene diradical of formula III:

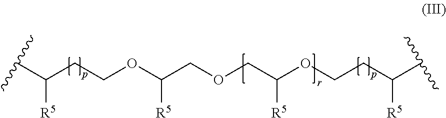

wherein p is 0 or 1, r is an integer from 1 to 100, and R⁵ is selected from H and a linear or branched C₁ to C₂₀ alkyl group;
R³ and R⁴ are monovalent groups independently selected from a linear or branched C₅ to C₃₀ alkyl group, a C₅ to C₃₀ cycloalkyl, a C₁ to C₂₀ hydroxyalkyl, and a C₂ to C₄ oxyalkylene homo or copolymers, all of which may optionally be substituted, and wherein pair-wise R³—R⁴ and adjacent R⁴—R⁴ and R³—R³ may optionally together form a bivalent group X, and may also be a continuation Q of the molecule by branching, and, if n is equal to or greater than 2, R³, R⁴ or R³ and R⁴ may also be hydrogen atoms;
n is an integer from 1 to 5, or, in case at least one of X, R³ and R⁴ comprises a C₂ to C₄ polyoxyalkylene group, n may be an integer from 1 to 10000, and provided that, if at least one Q is present, n includes all repeating units of branches Q;
Q is

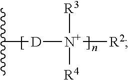

n is an integer from 1 to 5
D is a divalent group, for each repeating unit 1 to n independently selected from
   (a) linear or branched C₁ to C₂₀ alkanediyl,
   (b) C₅ to C₂₀ cycloalkanediyl,
   (c) C₅ to C₂₀ aryl,
   (d) C₆ to C₂₀ arylalkanediyl of formula —Z¹-A-Z²—, wherein Z¹ and Z² are independently selected from a C₁ to C₇ alkanediyl and A is a C₅ to C₁₂ aromatic moiety,
      all of which may optionally be substituted and which may optionally be interrupted by one or more heteroatoms selected from O, S, and N;
R⁵ is a monovalent groups independently selected from linear or branched, C₁ to C₂₀ alkyl, C₅ to C₂₀ cycloalkyl, C₅ to C₂₀ aryl, C₆ to C₂₀ alkylaryl, and C₆ to C₂₀ arylalkyl, which may optionally be substituted;

Gemini compounds and other compounds comprising more than one nitrogen atom in the core are formed in this way. Such compounds are described in more detail in U.S. provisional patent application No. 61/669,686, which is incorporated herein by reference.

Preferably the composition further comprises a surfactant. Such surfactant or surfactants may be anionic, cationic, non-ionic or zwitterionic surfactants.

Preferably the composition has a pH of 8 or more, more preferably a pH of from 9 to 14.

Preferably the substrate is a semiconductor substrate.

The bulky ammonium compound in the composition is used in an amount in order to prevent pattern collapse. The concentration of the bulky ammonium compounds additives in the developer solution are typically in the range of about 1.0·10⁻⁵ to about 1.5 N (based on ammonium groups or corresponding hydroxide), preferably about 1.0·10⁻⁴ to about 1.0 N, more preferably about 1.0·10⁻³ to about 0.8 N, most preferably about 0.05 to about 0.7 N

Z is a counter-ion and z is an integer, which is chosen so that the overall bulky quaternary ammonium compound is electrically uncharged.

Any type of organic or inorganic anion Z customary and known in the field of quaternary ammonium salts may be used as counter-ion for the cation of the general formula I. Preferably, Z is an anion Z^{x-} with x being selected from 1, 2, 3 or 4, preferably 1 or 2. Particular examples of suitable counter-ions are selected from hydroxide, chloride, bromide, nitrate, sulfate, monomethyl sulfate, formate, acetate and propionate ions without limiting the invention thereto. Most preferably hydroxide is used as counter-ion since hydroxide ions are anyhow present in the basic developer composition and contamination with other anions can be avoided.

With regard to the developer composition, any suitable commercial developer composition may be used in the invention with the proviso that the developer composition contain a bulky ammonium compound as described herein. Developer compositions are typically basic and may contain potassium hydroxide, sodium hydroxide, sodium silicate and the like as the principal component but it is highly preferred that the only basic component are the bulky ammonium compounds.

The optional additives used in conventional developer compositions may also be used in the developer compositions of the invention and include stabilizers and dissolving aids, and monohydric alcohols, which serve to remove residues of the photoresist which may otherwise be left on the exposed areas after development. These optional additives can be added to the inventive developing solution either singly or as a combination of two kinds or more according to need.

Besides water, water-soluble organic solvents may present, particular if negative photoresists are to be developed. Such organic solvents be an organic solvent miscible with water and other compounding components, and conventional cones may be employed. Specific examples include sulfoxides, such as dimethyl sulfoxide; sulfones, such as dimethylsulfone, diethylsulfone, bis(2-hydroxyethyl)sulfone, and tetramethylenesulfone (i. e., sulforane); amides, such as N, N-dimethylformamide, N-methylformamide, N, N-dimethylacetamide, N-methylacetamide, and N, N-diethylacetamide; lactams, such as N-methyl-2-pyrroldione, N-ethyl-2-pyrrolidone, N-propyl-2-pyrrolidone, N-hydroxymethyl-2-pyrrolidone, and N-hydroxyethyl-2-pyrrolidone; and polyhydric alcohols and derivatives thereof, such as ethylene glycol, ethylene glycol monomethyl ether, ethylene glycol monoethyl ether, ethylene glycol monobutyl ether, ethylene glycol monomethyl ether acetate, ethylene glycol monoethyl other acetate, diethylene glycol, diethylene glycol monomethyl ether, diethylene glycol monoethyl ether, diethylene glycol monobutyl ether, propylene glycol monomethyl ether, propylene glycol monoethyl ether, propylene glycol monopropyl ether, and propylene glycol monobutyl ether.

The developer compositions comprising the bulky ammonium compounds are preferably aqueous solutions.

“Aqueous” means that the solvent comprises water, preferably deionized water and, most preferably ultrapure water as the main solvent. The aqueous composition may contain water-miscible polar organic solvents, albeit only in such minor amounts that do not jeopardize the aqueous nature of the composition. It is preferred that the solvent essentially consists of water, preferably deionized water and, most preferably ultrapure water. Example of ultrapure water with concentration of 5 ppt (ng/kg), or better, anion concentration 5 ppb (ng/g), or better, total organic content (TOC) 50 ppb (ng/g), or better and contains particles of >0.2 mm under 10000 per ml.

Any type of surfactants, such as but not limited to anionic, cationic, non-ionic, or zwitterionic surfactants, may be used in the developer composition in order to improve surface tension and wetting capabilities. Typical amounts of surfactants useful in the composition are from about 10⁻⁴ to about 5% by weight.

The immersion time of the substrate may be a time sufficient for developing the photoresist pattern on the substrate and is not particularly limited, but is usually from about 5 seconds to 2 minutes. The processing temperature is preferably about 15-70° C., and particularly, about 20-30° C.

The Invention further provides a method for manufacturing integrated circuit devices, optical devices, micromachines and mechanical precision devices comprising the steps of
(i) providing a substrate
(ii) providing the substrate with a photoresist layer;
(iii) exposing the photoresist layer to actinic radiation through a mask with or without an immersion liquid;
(iii) contacting the substrate at least once with a composition as described herein to obtain a patterned photoresist layer;
and
(iv) removing the composition from the contact with the substrate.

Any customary and known substrates used for manufacturing IC devices, optical devices, micromachines and mechanical precision devices can be used in the process of the invention. Preferably, the substrate is a semiconductor substrate, more preferably a silicon wafer including a silicon-gallium wafer, which wafers are customarily used for manufacturing IC devices, in particular IC devices comprising ICs having LSI, VLSI and ULSI.

The composition is particularly suitable for treating substrates having patterned material layers having structure dimensions of 100 nm or less, in particular, 50 nm and less and, in particular 32 nm or less, especially, 22 nm or less, i.e. patterned material layers for the sub-22 nm technology nodes. The patterned photoresist layers preferably have aspect ratios above 2.

The composition according to the present invention may be applied to photoresists deposited on substrates of any material. By way of example, the substrate may be

(a) barrier material layers containing or consisting of ruthenium, titanium nitride, tantalum or tantalum nitride,
(b) multi-stack material layers containing or consisting of layers of at least two different materials selected from the group consisting of silicon, polysilicon, silicon dioxide, low-k and ultra-low-k materials, high-k materials, semiconductors other than silicon and polysilicon and metals; and
c) dielectric material layers containing or consisting of silicon dioxide or low-k or ultra-low-k dielectric materials.

Any customary and known positive or negative immersion photoresist, EUV photoresist or eBeam photoresist can be used. Additionally, the immersion photoresist can contain nonionic surfactants. Suitable nonionic surfactants are described, for example, in US 2008/0299487 A1, page 6, paragraph [0078]. Most preferably, the immersion photoresist is a positive resist. Preferably the photoresist is an immersion photoresist, an EUV photoresist or eBeam photoresist.

After the development of the photoresist the developer composition is removed from the substrate by using an aqueous rinsing liquid. Any known rinsing liquid may be used in this case.

### BRIEF DESCRIPTION OF THE DRAWINGS

FIG. 1 schematically shows pattern collapse due to capillary action in conjunction with factor such as swelling and softening.

FIG. 2 schematically shows the effect of the bulky hydrophobic group with respect to preventing the polymer swelling

FIG. 3 shows a profile of a photoresist pattern developed with a developer comprising trimethyladamantylammonium hydroxide according to example 1

FIG. 4 shows a profile of a photoresist pattern developed with a developer comprising tetramethylammonium hydroxide (TMAH) according to comparative example 2

FIG. 5 shows a profile of a photoresist pattern developed with a developer comprising dimethyldicyclohexylammonium hydroxide according to example 3

FIG. 6 shows a profile of a photoresist pattern developed with a developer comprising tetramethylammonium hydroxide (TMAH) according to comparative example 4

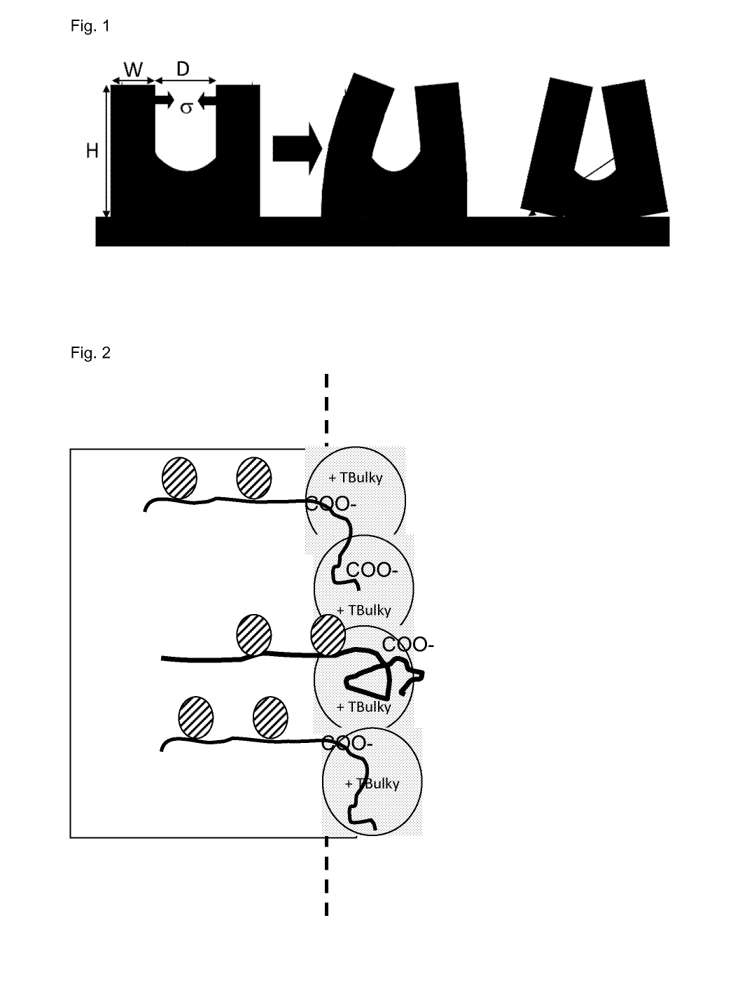

### EXAMPLES

### Example 1

Photoresist layers having features with line-space structures and line-width of 26 nm (feature dimension) and an aspect ratio of about 4 were developed using a developer composition comprising trimethyladamantylammonium hydroxide (D1). The space between the photoresist lines was 52 nm.

Silicon wafers were provided with 100 nm thick layers of an immersion photoresist. The photoresist layers were exposed to UV radiation of a wavelength of 193 through a mask using ultrapure water as the immersion liquid. Thereafter, the exposed photoresist layers were baked and developed with an aqueous developer solution containing 0.26 N of D1. The baked and developed photoresist layers were subjected to a chemical rinse treatment using a chemical rinse solution containing tetramethylammonium hydroxide (TMAH).

The chemical rinse solution was applied on the wafer as a puddle. Thereafter, the silicon wafers were spun dry.

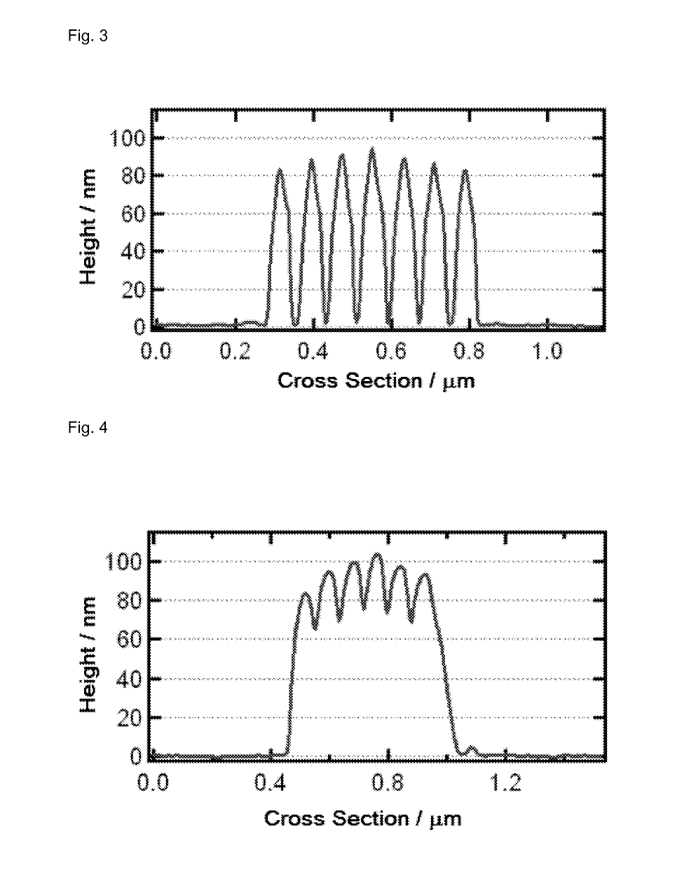

FIG. 3 shows the respective height profile measured by AFM after development with D1 and rinse treatment. The dried patterned photoresist layers having patterns with line-space dimensions of 26 nm and an aspect ratio of about 4 did not show any pattern collapse. The deep trenches in the photoresist indicate a low swelling of the photoresist.

### Comparative Example 2

Example 1 was repeated except that 0.26 N tetramethylammonium hydroxide (D3) was used instead of surfactant D1 in the photoresist developer solution.

FIG. 4 shows the result of a photoresist development treatment by using TMAH. The dried patterned photoresist layers having photoresist line-width dimensions of 26 nm and an aspect ratio of about 4 showed significantly increased pattern collapse compared to example 1. The shallow trenches in the photoresist indicate a strong swelling of the photoresist.

### Example 3

Example 1 was repeated except that 0.26 N dimethyldicyclohexylammonium hydroxide (D2) was used instead of surfactant D1 in the photoresist developer solution and the line width was 40 nm and the space between the photoresist lines was 80 nm.

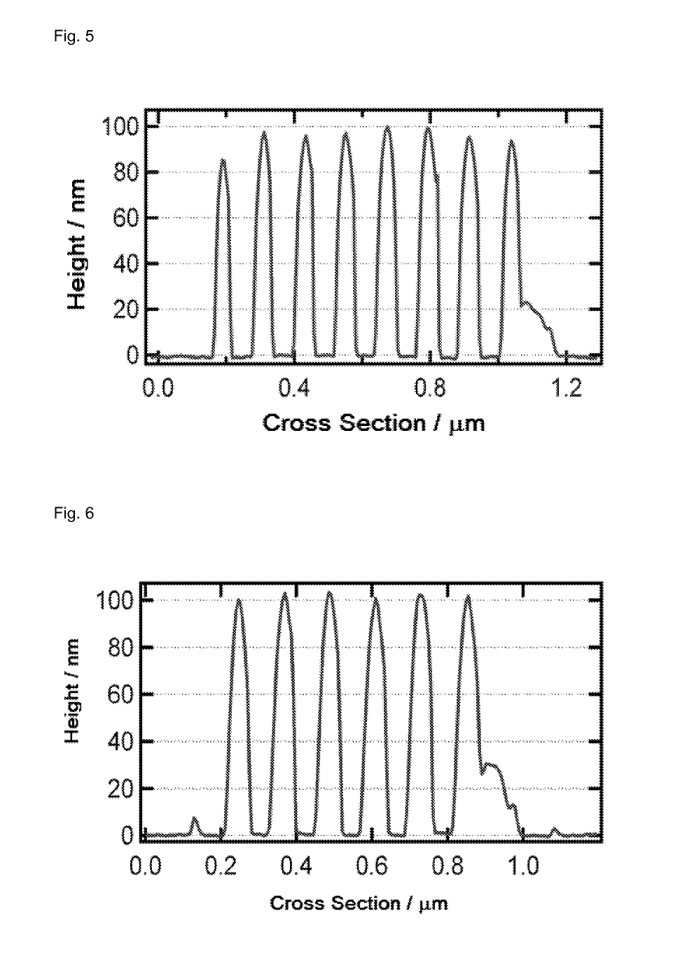

FIG. 5 shows the respective height profile measured by AFM after development with D2 and rinse treatment. The dried patterned photoresist layers having photoresist line-width dimensions of 40 nm and an aspect ratio of about 2.5 did not show any pattern collapse. The deep trenches in the photoresist indicate a low swelling of the photoresist.

### Comparative Example 4

Example 3 was repeated except that 0.26 N D3 was used instead of D2 in the photoresist developer solution.

FIG. 6 shows the result of a photoresist development treatment by using D3. The dried patterned photoresist layers having photoresist line-width dimensions of 40 nm and an aspect ratio of about 2.5 showed significantly increased pattern collapse compared to example 3.

1. An aqueous composition, comprising a quaternary ammonium compound of formula I 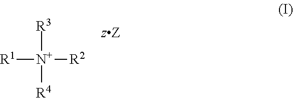
wherein
(a) R¹ is selected from a C₄ to C₃₀ organic radical of formula —X—CR¹⁰R¹¹R¹², wherein R¹⁰, R¹¹ and R¹² are independently selected from a C₁ to C₂₀ alkyl and two or three of R¹⁰, R¹¹ and R¹² may together form a ring system, and
R², R³ and R⁴ are selected from R¹ or a C₁ to C₁₀ alkyl, C₁ to C₁₀ hydroxyalkyl C₁ to C₃₀ aminoalkyl or C₁ to C₂₀ alkoxyalkyl, and X is a chemical bond or a C₁ to C₄ divalent organic radical, or
(b) R¹ and R² are independently selected from an organic radical of formula IIa or IIb 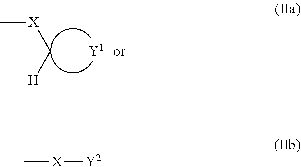
wherein Y¹ is C₄ to C₂₀ alkanediyl, Y² is a one-, two- or tricyclic C₅ to C₂₀ carbocyclic or heterocyclic aromatic system, and R³ and R⁴ are selected from R¹ or a C₁ to C₁₀ alkyl, C₁ to C₁₀ hydroxyalkyl, C₁ to C₃₀ aminoalkyl, or C₁ to C₂₀ alkoxyalkyl, and X is a chemical bond or a C₁ to C₄ divalent organic radical, and X is a chemical bond or a C₁ to C₄ divalent organic radical, or
(c) at least two of R¹, R², R³, and R⁴ together form a saturated mono, bi or tricyclic C₅ to C₃₀ organic ring system and the remaining R³ and R⁴, if any, together form a monocyclic C₅ to C₃₀ organic ring system or are selected from a C₁ to C₁₀ alkyl, C₁ to C₁₀ hydroxyalkyl, C₁ to C₃₀ aminoalkyl, or C₁ to C₂₀ alkoxyalkyl, and X is a chemical bond or a C₁ to C₄ divalent organic radical, or
(d) a combination thereof, and
wherein Z is a counter-ion and z is an integer, which is chosen so that the overall bulky quaternary ammonium compound is electrically uncharged.

2. The aqueous composition according to claim 1, wherein R¹⁰, R¹¹, and R¹² of R¹ are independently selected from C₁ to C₈ alkyl and R², R³ and R⁴ are independently selected from C₁ to C₄ alkyl.

3. The aqueous composition according to claim 1, wherein
R¹, R² are independently selected from cyclohexyl, cyclooctyl or cyclodecyl, which may be unsubstituted or substituted by C₁ to C₄ alkyl, and
R³, R⁴ are independently selected from C₁ to C₄ alkyl.

4. The aqueous composition according to claim 1, wherein the C₁ to C₃₀ aminoalkyl is selected from 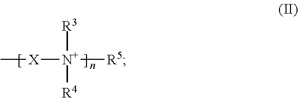
wherein:
X is a divalent group, for each repeating unit 1 to n independently selected from
(a) linear or branched C₁ to C₂₀ alkanediyl, which may optionally be substituted and which may optionally be interrupted by up to 5 heteroatoms selected from O and N,
(b) C₅ to C₂₀ cycloalkanediyl, which may optionally be substituted and which may optionally be interrupted by up to 5 heteroatoms selected from O and N,
(c) C₆ to C₂₀ organic group of formula —X¹-A-X²—, wherein X¹ and X² are independently selected from a C₁ to C₇ linear or branched alkanediyl and A is selected from a C₅ to C₁₂ aromatic moiety or a C₅ to C₃₀ cycloalkanediyl, which H atoms may optionally be substituted and which C atoms may optionally be interrupted by up to 5 heteroatoms selected from O and N,
(d) polyoxyalkylene diradical of formula III: 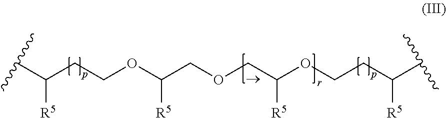
wherein p is 0 or 1, r is an integer of from 1 to 100, and R⁵ is selected from H and a linear or branched C1 to C20 alkyl group;
R³ and R⁴ are monovalent groups independently selected from a linear or branched C₅ to C₃₀ alkyl group, a C₅ to C₃₀ cycloalkyl, a C₁ to C₂₀ hydroxyalkyl, and a C₂ to C₄ oxyalkylene homo or copolymers, all of which may optionally be substituted, and wherein pair-wise R³—R⁴ and adjacent R⁴—R⁴ and R³—R³ may optionally together form a bivalent group X, and may also be a continuation Q of the molecule by branching, and, if n is equal to or greater than 2, R³, R⁴ or R³ and R⁴ may also be hydrogen atoms;
n is an integer from 1 to 5, or, in case at least one of X, R³ and R⁴ comprises a C₂ to C₄ polyoxyalkylene group, n may be an integer from 1 to 10000, and provided that, if Q is present, n includes all repeating units of branches Q;
Q is 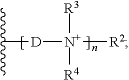
n is an integer of from 1 to 5
D is a divalent group, for each repeating unit 1 to n independently selected from
(a) linear or branched C₁ to C₂₀ alkanediyl,
(b) C₅ to C₂₀ cycloalkanediyl,
(c) C₅ to C₂₀ aryl,
(d) C₆ to C₂₀ arylalkanediyl of formula —Z¹-A-Z²—, wherein Z¹ and Z² are independently selected from a C₁ to C₇ alkanediyl and A is a C₅ to C₁₂ aromatic moiety,
all of which may optionally be substituted and which may optionally be interrupted by at least one heteroatom selected from the group consisting of O, S, and N; and
R⁵ is a monovalent group independently selected from linear or branched, C₁ to C₂₀ alkyl, C₅ to C₂₀ cycloalkyl, C₅ to C₂₀ aryl, C₆ to C₂₀ alkylaryl, and C₆ to C₂₀ arylalkyl, which may optionally be substituted.

5. (canceled)

6. The aqueous composition according to claim 1, wherein at least two of R¹⁰, R¹¹ and R¹² together form a mono, bi or tri cyclic ring system.

7. The aqueous composition according to claim 1, wherein R¹ is selected from bicyclo[2.2.1]heptane, Tricyclo[3.3.1.1^{3,7}]decane and R², R³ and R⁴ are independently selected from linear C₁ to C₄ alkyl.

8. The aqueous composition according to claim 1, wherein R¹ and R² are selected from C₅ to C₁₀ cycloalkyl and R³ and R⁴ are independently selected from linear C₁ to C₄ alkyl.

9. The aqueous composition according to claim 1, further comprising a surfactant.

10. The aqueous composition according to claim 1, wherein Z is OH⁻.

11. The aqueous composition according to claim 1, the composition having a pH of 8 or more.

12. The composition according to claim 1, wherein the composition is suitable for developing photoresist layers applied to semiconductor substrates to obtain a patterned photoresist layer having line-space dimensions of 50 nm or less and an aspect ratio of 2 or more.

13. A method for manufacturing integrated circuit devices, optical devices, micromachines and mechanical precision devices, the method comprising:
contacting a substrate with a photoresist layer;
exposing the photoresist layer to actinic radiation through a mask with or without an immersion liquid;
contacting the substrate at least once with an aqueous composition according to claim 1 to obtain a patterned photoresist layer; and
removing the composition from the contact with the substrate.

14. The method according to claim 13, wherein the substrate is a semiconductor substrate.

15. The method according to claim 13, wherein the patterned material layers have a feature dimension of 50 nm or less and an aspect ratio of more than 2.

16. The method according to claim 13, wherein the photoresist is an immersion photoresist, an EUV photoresist or eBeam photoresist.

17. The method according to claim 13, the integrated circuit devices comprise integrated circuits have a large-scale integration (LSI), very-large-scale integration (VLSI) or ultra-large-scale integration (ULSI).

18. The composition according to claim 1, wherein the solvent consists essentially of water.

19. The aqueous composition according to claim 1, the composition having a pH of from 9 to 14.
